(19) United States
(12) Patent Application Publication
(10) Pub. No.: US 2025/0143030 A1
(43) Pub. Date: May 1, 2025

(54) LIGHT-EMITTING DIODE AND LIGHT-EMITTING DEVICE

(71) Applicant: XIAMEN SAN'AN OPTOELECTRONICS CO., LTD., Xiamen (CN)

(72) Inventors: SHIWEI LIU, Xiamen (CN); JIN XU, Xiamen (CN); CHUNG-YING CHANG, Xiamen (CN); SHUIJIE WANG, Xiamen (CN); YU-TSAI TENG, Quanzhou (CN); QING WANG, Xiamen (CN); BAOJUN SHI, Xiamen (CN); JIPU WU, Xiamen (CN); KUNTA HSIEH, Quanzhou (CN); KE LIU, Xiamen (CN); DAZHONG CHEN, Xiamen (CN)

(21) Appl. No.: 19/010,429

(22) Filed: Jan. 6, 2025

Related U.S. Application Data
(63) Continuation of application No. PCT/CN2021/129687, filed on Nov. 10, 2021.

(51) Int. Cl. H10H 20/841

(52) U.S. Cl. CPC H10H 20/841

(57) ABSTRACT

A light-emitting diode includes an epitaxial layer, including a first semiconductor layer, a light-emitting layer configured to emit light, and a second semiconductor layer sequentially stacked in that order, and has a first surface and a second surface opposite to each other; a first insulating reflective layer, disposed on the first surface of the epitaxial layer; and a second insulating reflective layer, disposed on the second surface of the epitaxial layer. Reflectivity of the first insulating reflective layer to light with a first incident angle is lower than reflectivity of the second insulating reflective layer to light with a third incident angle, the first incident angle is in a range of 0° to 10°, and the third incident angle is in a range of 0° to 10°. Therefore, a lateral light emission angle and an extreme light emission angle of the light-emitting diode can be improved, which meet market demand.

### CROSS-REFERENCE TO RELATED APPLICATION

This application is a continuation of International Patent Application No. PCT/CN2021/129687, filed on Nov. 10, 2021, which is herein incorporated by reference in its entirety.

### TECHNICAL FIELD

The disclosure relates to the technical field of light-emitting diodes, and more particularly to a light-emitting diode and a light-emitting device with a large light-emitting angle.

### BACKGROUND

Light-emitting diode (LED) is a semiconductor light-emitting element, which is usually prepared by semiconductors such as gallium nitride (GaN), gallium arsenide (GaAs), gallium phosphide (GaP) and gallium arsenide phosphide (GaAsP). A core of LED is a PN junction with light-emitting characteristics. Under forward voltage, electrons are injected from an N region to a P region, holes are injected from the P region to the N region, and part of minority carriers entering the opposite region are combined with majority carriers to emit light. The LED has advantages of low cost, high light efficiency, and energy conservation and environmental protection, and is widely applied in scenarios such as lighting, visible light communication, and light-emitting display.

For backlight application, Mini-LED generally adopts a direct-lit backlight design. Region dimming in a smaller range can be achieved through a large number of dense distributions of chips. Compared with a traditional backlight design, the Mini-LED can achieve better brightness uniformity, higher contrast ratio in a smaller light mixing distance, and does not require additional lenses for secondary light distribution, so as to achieve thinner end products, high color rendering and power saving.

In terms of achieving the same light mixing effect and light-emitting uniformity, the use of Mini-LED chips without large-angle light emission requires a tighter chip arrangement and a larger number of chips. The chip arrangement required by the use of Mini-LED chips with large-angle light emission requires is relatively sparse, and the number of chips is small. Therefore, the use of the Mini-LED chips with large-angle light emission can greatly reduce the number of chips of the Mini-LED used in a backlight display device, thereby reducing the cost of the backlight display device.

In order to ensure large-angle light emission of the LED chips, current LED chips adopt full-angle reflective layers such as metal vapor deposition and a distributed Bragg reflector (DBR) on a light-emitting surface of a substrate of a flip-chip LED chip to control the light emit from a side of the chip, to thereby increase the light emission angle of the chip. Although this method can achieve light emission from the side of the chip, since the light emitted from the side of the chip exists in all directions, an extreme light emission angle is not large enough to meet the uniformity requirement. For example, as shown in FIG. 9 and FIG. 10, in the existing LED chips with large-angle light emission, the DBR reflective layers on both sides of the substrate have high reflectivity characteristics for light at any incident angle, and their included angles of the lateral extreme light emission are about 90°, and a ratio of light intensity of the lateral extreme light to light intensity of axial light is about 2. This lateral light emission angle cannot meet the market demand.

### SUMMARY

The disclosure provides a light-emitting diode, which includes an epitaxial layer, a first insulating reflective layer and a second insulating reflective layer.

The epitaxial layer includes a first semiconductor layer, a light-emitting layer configured to emit light, and a second semiconductor layer sequentially stacked in that order, and has a first surface and a second surface opposite to each other. The first insulating reflective layer is disposed on a side of the first surface of the epitaxial layer. The second insulating reflective layer is disposed on a side of the second surface of the epitaxial layer. Reflectivity of the first insulating reflective layer to light with a first incident angle is lower than reflectivity of the second insulating reflective layer to light with a third incident angle, the first incident angle is in a range of 0° to 10°, and the third incident angle is in a range of 0° to 10°.

The disclosure further provides a light-emitting diode, which includes an epitaxial layer and a first insulating reflective layer.

The epitaxial layer includes a first semiconductor layer, a light-emitting layer configured to emit light, and a second semiconductor layer sequentially stacked in that order, and has a first surface and a second surface opposite to each other. The first insulating reflective layer is disposed on a side of the first surface of the epitaxial layer. Reflectivity of the first insulating reflective layer to light with a first incident angle is lower than 90%, and the first incident angle is in a range of 0° to 10°.

The disclosure further provides a light-emitting diode, which includes an epitaxial layer and a first insulating reflective layer.

The epitaxial layer includes a first semiconductor layer, a light-emitting layer configured to emit light, and a second semiconductor layer sequentially stacked in that order, and has a first surface and a second surface opposite to each other. The first insulating reflective layer is disposed on a side of the first surface of the epitaxial layer. Reflectivity of the first insulating reflective layer to light with a first incident angle is lower than reflectivity of the first insulating reflective layer to light with a second incident angle, and the first incident angle is smaller than the second incident angle.

In an embodiment, the first incident angle is in a range of 0° to 10°, and the second incident angle is in a range of 60° to 90°.

In an embodiment, the reflectivity of the first insulating reflective layer to the light with the first incident angle is lower than 90%, and the reflectivity of the first insulating reflective layer to the light with the second incident angle is at least 90%. The second incident angle is greater than the first incident angle, and the second incident angle is in a range of 60° to 90°.

In an embodiment, the reflectivity of the first insulating reflective layer to the light with the second incident angle is higher than reflectivity of the second insulating reflective layer to light with a fourth incident angle, and the second incident angle and the fourth incident angle are in a range of 60° to 80°.

In an embodiment, a central radiation wavelength of the light emitted by the light-emitting layer is in a range of 430 nanometers (nm) to 460 nm.

In an embodiment, the reflectivity of the second insulating reflective layer to the light with the third incident angle is at least 90%.

In an embodiment, the reflectivity of the second insulating reflective layer to the light with the fourth incident angle is lower than 90%, and the fourth incident angle is in a range of 60° to 80°.

In an embodiment, each of the first insulating reflective layer and the second insulating reflective layer includes a multilayer structure formed by repeatedly stacking first refractive index material layers and second refractive index material layers.

In an embodiment, a thickness of the first insulating reflective layer is smaller than or equal to 4 microns (μm), and a thickness of the second insulating reflective layer is smaller than or equal to 3 μm.

In an embodiment, the reflectivity of the first insulating reflective layer to the light with the second incident angle is higher than the reflectivity of the first insulating reflective layer to the light with the first incident angle, the second incident angle is greater than the first incident angle, and the second incident angle is in a range of 60° to 90°.

In an embodiment, the reflectivity of the first insulating reflective layer to the light with the first incident angle is lower than 90%, and the reflectivity of the first insulating reflective layer to the light with the second incident angle is at least 90%.

In an embodiment, the light-emitting diode further includes a second insulating reflective layer, and the second insulating reflective layer is disposed on the second surface of the epitaxial layer.

In an embodiment, the reflectivity of the second insulating reflective layer to the light with the third incident angle is at least 90%, and the third incident angle is in a range of 0° to 20°. Specifically, the third incident angle is in a range of 0° to 10°.

In an embodiment, the reflectivity of the second insulating reflective layer to the light with the fourth incident angle is lower than 90%, and the fourth incident angle are in a range of 60° to 80°.

In an embodiment, the reflectivity of the first insulating reflective layer to the light with the first incident angle is lower than 90%, and the reflectivity of the first insulating reflective layer to the light with the second incident angle is at least 90%.

In an embodiment, the light-emitting diode further includes a second insulating reflective layer, and the second insulating reflective layer is disposed on a side of the second surface of the epitaxial layer. The reflectivity of the second insulating reflective layer to the light with the third incident angle is higher than the reflectivity of the second insulating reflective layer to the light with the fourth incident angle, and the third incident angle is smaller than the fourth incident angle. The third incident angle is in a range of 0° to 20°, and the fourth incident angle are in a range of 60° to 80°.

In an embodiment, the reflectivity of the second insulating reflective layer to the light with the third incident angle is at least 90%, and the reflectivity of the second insulating reflective layer to the light with the fourth incident angle is lower than 90%.

In an embodiment, the light-emitting diode is a flip-chip light-emitting diode, and a light-transmitting substrate is disposed between the second insulating reflective layer and the epitaxial layer.

In an embodiment, the light-emitting diode is a front-chip light-emitting diode, and a light-transmitting substrate is disposed between the first insulating reflective layer and the epitaxial layer.

The disclosure further provides a light-emitting device, which adopts any of the aforementioned light-emitting diodes. In an embodiment, the light-emitting device can be a backlight display device.

The disclosure provides a light-emitting diode and a light-emitting device, through the settings of selective reflection of the first insulating reflective layer and the second insulating reflective layer for different incident light, axial light emission of the light-emitting diode can be reduced, lateral light emission of the light-emitting diode can be increased, which greatly improves a lateral light emission angle of the light-emitting diode, and increases an extreme light emission angle of the light-emitting diode, thereby meeting requirement of light-emitting uniformity.

Other features and beneficial effects of the disclosure will be described in the following specification, and in part will become apparent from the specification, or may be learned by practicing the disclosure. Purposes and other beneficial effects of the disclosure can be achieved and obtained by structures specifically pointed out in contents such as the specification and claims.

### BRIEF DESCRIPTION OF DRAWINGS

In order to more clearly illustrate technical solutions in embodiments of the disclosure or the related art, accompanying drawings required in descriptions of the embodiments or the related art will be simply introduced. Apparently, the accompanying drawings in the following descriptions are some of the embodiments of the disclosure. For those skill in the art, other drawings can also be obtained from these drawings without creative work. Unless otherwise specified, the positional relationships described in the drawings in the following descriptions are based on directions indicated by the components in the drawings.

FIG. 1 illustrates a schematic structural diagram of a light-emitting diode according to an embodiment of the disclosure.

FIG. 2 illustrates a schematic light-emitting diagram of the light-emitting diode according to the embodiment of the disclosure.

FIG. 3 illustrates a schematic structural diagram of a second insulating reflective layer of the light-emitting diode with a middle area and surrounding areas according to an embodiment of the disclosure.

FIG. 4 illustrates a schematic diagram of measured reflectivity of a first insulating reflective layer and the second insulating reflective layer of the light-emitting diode on light at different incident angles according to the embodiment of the disclosure.

FIG. 5 illustrates a schematic diagram of an optical thickness of the first insulating reflective layer shown in FIG. 4.

FIG. 6 illustrates a schematic diagram of an optical thickness of the second insulating reflective layer shown in FIG. 4.

FIG. 7 illustrates a schematic diagram of a light distribution curve of the light-emitting diode shown in FIG. 1 measured by using a distributed photometer.

FIG. 8 illustrates a schematic diagram of measured reflectivity of the first insulating reflective layer and the second insulating reflective layer of the light-emitting diode on the light at different incident angles according to another embodiment of the disclosure.

FIG. 9 illustrates a schematic diagram of reflectivity of DBR reflective layers on two sides of an existing LED chip with large-angle light emission on light with different incident angles.

FIG. 10 illustrates a schematic diagram of a light distribution curve of the LED chip with large-angle light emission shown in FIG. 9 measured by using the distributed photometer.

FIG. 11 illustrates a schematic structural diagram of a front-chip light-emitting diode according to an embodiment of the disclosure.

### DESCRIPTION OF REFERENCE SIGNS

1, 5—light-emitting diode; 12—light-transmitting substrate; 14—epitaxial layer; 141—first semiconductor layer; 142—light-emitting layer; 143—second semiconductor layer; 144—first surface; 145—second surface; 16—first insulating reflective layer; 161—first opening; 162—second opening; 18—second insulating reflective layer; 181—middle area; 182—surrounding area; 21—first electrode; 22—second electrode; 31—first solder pad; 32—second solder pad; a—first incident angle; b—second incident angle; c—third incident angle; d—fourth incident angle.

### DETAILED DESCRIPTION OF EMBODIMENTS

In order to make purpose, technical solutions and advantages of embodiments of the disclosure clearer, the technical solutions in the embodiments of the disclosure will be clearly and completely described below in conjunction with drawings in the embodiments of the disclosure. Apparently, the described embodiments are some of the embodiments of the disclosure, rather than all of them. The technical features designed in the different embodiments of the disclosure described below can be combined as long as they do not constitute conflicts. Based on the embodiments of the disclosure, all other embodiments obtained by those skill in the art without creative work fall within a protection scope of the disclosure.

In the descriptions of the disclosure, it should be understood that terms “center”, “lateral”, “up”, “down”, “left”, “right”, “vertical”, “horizontal”, “top”, “bottom”, “inside” and “outside” indicate orientation or positional relationships based on the orientation or positional relationships shown in the accompanying drawings, which are only used for the convenience of describing the disclosure and simplifying the descriptions, and do not indicate or imply that the device or component referred to must have a specific orientation or be constructed and operated in a specific orientation, and therefore cannot be understood as a limitation of the disclosure. In addition, terms “first” and “second” are used for descriptive purposes only, and cannot be interpreted as indicating or implying relative importance or implicitly specifying the quantity of indicated technical features. Thus, a feature defined as “first” and “second” may explicitly or implicitly include one or more of these features. In the description of the disclosure, unless otherwise specified, “multiple” means two or more. In addition, a term “comprising” and any variations thereof mean “at least comprising”.

In the descriptions of the disclosure, it should be noted that unless otherwise specified and limited, terms “installation”, “connection” and “connected” should be understood in a broad sense. For example, it can be a fixed connection, a detachable connection, or an integrated connection; it can be a mechanical connection or an electrical connection; it can be a direct connection or an indirect connection through an intermediary, and it can be the internal communication of two components. Those skilled in the art can understand the specific meanings of the above terms in the disclosure in specific situations.

The terms used herein are for the purpose of describing particular embodiments only and are not intended to be limiting of exemplary embodiments. Unless the context clearly dictates otherwise, the singular forms “a” and “one” used here are intended to include the plural. It should also be understood that terms “comprising” and/or “including” as used herein specify the presence of stated features, integers, steps, operations, units and/or components, but do not exclude the presence or addition of one or more other features, integers, steps, operations, units, components and/or combinations thereof.

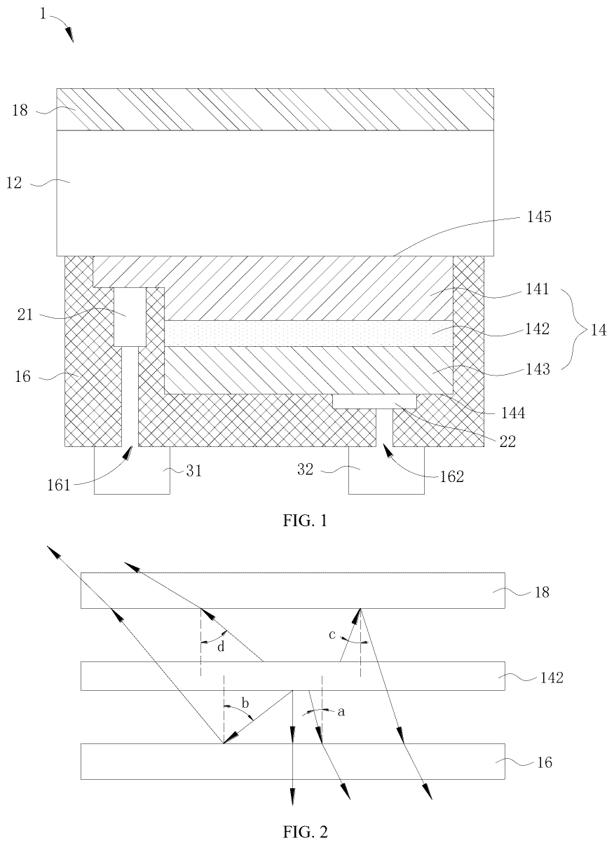

Referring to FIG. 1, FIG. 1 illustrates a schematic structural diagram of a light-emitting diode 1 according to an embodiment of the disclosure. In order to achieve at least one of the advantages or other advantages of the disclosure, an embodiment of the disclosure provides a light-emitting diode 1. As shown in FIG. 1, the light-emitting diode 1 includes an epitaxial layer 14, a first insulating reflective layer 16 and a second insulating reflective layer 18.

A light-transmitting substrate 12 is located between the epitaxial layer 14 and the second insulating reflective layer 18. The epitaxial layer 14 is disposed on the light-transmitting substrate 12, includes a first semiconductor layer 141, a light-emitting layer 142 and a second semiconductor layer 142 sequentially stacked in that order from bottom to up, and has a first surface 144 and a second surface 145 opposite to each other. The light-transmitting substrate 12 can be a transparent substrate or a translucent substrate. Specifically, the transparent substrate or the translucent substrate can allow light emitted by the light-emitting layer 142 to pass through the light-transmitting substrate 12 and reach a side of the light-transmitting substrate 12 facing away from the epitaxial layer 14. For example, the light-transmitting substrate 12 can be any one selected from the group consisting of a sapphire flat substrate, a sapphire patterned substrate, a silicon substrate, a silicon carbide substrate, a gallium nitride substrate, and a glass substrate. In an embodiment, the light-transmitting substrate 12 is a sapphire patterned substrate. The light-emitting diode 1 emits light from the side of the light-transmitting substrate 12. A thickness of the light-transmitting substrate 12 can be in a range of 60 μm to 150 μm.

In the embodiment, the first surface 144 refers to a side of the second semiconductor layer 143 facing away from the light-emitting layer 142, and the second surface 145 refers to a side of the first semiconductor layer 141 facing away from the light-emitting layer 142. In other words, the first surface 144 and the second surface 145 respectively correspond to a lower side and an upper side of the epitaxial layer 14 in FIG. 1.

The first semiconductor layer 141 is formed on the light-transmitting substrate 12. The first semiconductor layer 141 is grown on the light-transmitting substrate 12, and can be doped with n-type impurifies, for example, it is a gallium nitride semiconductor layer of silicon (Si). In some embodiments, a undoped buffer layer can be inserted between the first semiconductor layer 141 and the light-transmitting substrate 12, to provide a buffering effect, thereby avoiding a problem of poor quality of the semiconductor layers caused by significant lattice differences between the first semiconductor layer 141 and the light-transmitting substrate 12. In other embodiments, the epitaxial layer 14 can also be bonded to the light-transmitting substrate 12 through an adhesive layer.

The light-emitting layer 142 can be a quantum well (QW) structure. In other embodiments, the light-emitting layer 142 can be a multiple quantum well (MQW) structure, and the MQW structure includes multiple quantum well layers and multiple quantum barrier layers stacked repeatedly and alternately.

In addition, a composition and thicknesses of the well layers in the light-emitting layer 142 determine a wavelength of generated light. Particularly, the light-emitting layer 142 generating different color light such as blue light and green light can be provided by adjusting the composition of the well layers. In an embodiment, as light-emitting element used for backlight display, the light emitted by the light-emitting layer 142 appears as blue light, and a central radiation wavelength is in a range of 430 nm to 460 nm.

The second semiconductor layer 143 can be doped with p-type impurifies, for example, it is a gallium nitride semiconductor layer of magnesium (Mg). The first semiconductor layer 141 and the second semiconductor layer 143 each can be a single-layer structure, but the disclosure is not limited to this, the first semiconductor layer 141 and the second semiconductor layer 143 each can also be a multilayer structure, and can also include a superlattice layer. In addition, in a situation that the first semiconductor layer 141 is doped with the p-type impurifies, the second semiconductor layer 143 can be doped with the n-type impurifies.

The first insulating reflective layer 16 and the second insulating reflective layer 18 are respectively disposed on the first surface 144 and the second surface 145 of the epitaxial layer 14. The first insulating reflective layer 16 and the second insulating reflective layer 18 each include a DBR layer. The DBR layer is formed by stacking films with different refractive indices alternately and periodically, that is, the DBR layer is a periodical film formed by stacking high refractive index materials and low refractive index materials alternately. Refractive indices, thicknesses, and stacking quantity of the various films that form the DBR layer are adjusted to achieve that the DBR layer has different transmissivity and reflectivity for light at different incident angles. In other words, each of the first insulating reflective layer 16 and the second insulating reflective layer 18 can be a multilayer structure formed by repeatedly stacking high refractive index material layers (i.e., first refractive index material layer) and low refractive index material layers (i.e., second refractive index material layer), so that the first insulating reflective layer 16 and the second insulating reflective layer 18 can have different transmissivity and reflectivity according to change in the incident angle of light.

In the related art, a function of the first insulating layer is to reflect back light emitted from the epitaxial layer to the first surface, and allow the light to be mainly emit out from a side surface of the light-transmitting substrate. A function of the second insulating layer is to reduce a ratio of light emitted at small angles from a front of the substrate, and increase a ratio of light emitted at large angles from a side surface of the substrate. However, in the related art, it is not considered that the first insulating layer and the second insulating layer can selectively adjust the light at different angles, thereby increasing a final light emission angle range of the chip, that is, increasing the light intensity ratio of the lateral light, so as to improve the light emission uniformity. Based on this, the disclosure provides the following designs, the reflectivity of the first insulating reflective layer 16 and the second insulating reflective layer 18 to light generated by the light-emitting layer 142 when powered on and light emitted on the surfaces of the first insulating reflective layer 16 and the second insulating reflective layer 18 is adjusted to achieve the purpose of the disclosure.

Specifically, as shown in FIG. 2, for the light incident to the surface of the first insulating reflective layer 16 at a small angle, that is, defined as light with a first incident angle a, reflectivity of the first insulating reflective layer 16 is reduced, that is, transmissivity of the first insulating reflective layer 16 to the light with the first incident angle a is improved. In this way, the first insulating reflective layer 16 transmits at least a part of the light with a small incident angle, thereby reducing the light emitted from the surface of the second insulating reflective layer 18 at a small angle, and increasing a light emission ratio of the light emitted from a large angle.

In an embodiment, the reflectivity of the first insulating reflective layer 16 to the light with the first incident angle a is lower than 90%. In an embodiment, the reflectivity of the first insulating reflective layer 16 is in a range of 50% to 90%, and low reflectivity can lead to brightness loss. In an embodiment, the reflectivity is in a range of 60% to 70%, 70% to 80% or 90% to 90%.

In an embodiment, the first incident angle a is in a range of 0° to 10°, which can include vertically incident axial light at 0° and light at a small incident angle greater than 0° and smaller than or equal to 10° within the range of 0° to 10°. Compared with the traditional insulating reflective layer, the first insulating reflective layer 16 has a lower reflectivity for light with an incident angle in the range of 0° to 10°.

In an embodiment, the second insulating reflective layer 18 can effectively reflect the light with the small incident angle (including vertically incident light), thereby reducing the ratio of light emitted from the surface of the second insulating reflective layer 18 at small angles, and increasing the light emission ratio of light at large angles. The light with the small incident angle incident on the surface of the second insulating reflective layer 18 is defined as light with a third incident angle c. In an embodiment, the second insulating reflective layer 18 has high reflectivity to the light with the third incident angle c. In an embodiment, the reflectivity is at least 90%, for example, 90% to 100%, for example, 95%, 96%, 97%, 98% or 99%.

In an embodiment, the third incident angle c is in a range of 0° to 20°, that is, the second insulating reflective layer 18 has high reflectivity to vertically incident axial light at 0° and light at the small incident angle greater than 0° and smaller than or equal to 20° within the range of 0° to 20°, and the reflectivity is at least 90%. In an embodiment, for example, 90% to 100%, for example, 95%, 96%, 97%, 98% or 99%. In other words, the reflectivity of the first insulating reflective layer 16 to the light with the first incident angle a is lower than the reflectivity of the second insulating reflective layer 18 to the light with the third incident angle c, the first incident angle a is in a range of 0° to 10°, and the third incident angle c is in a range of 0° to 20°. In an embodiment, the third incident angle c is in a range of 0° to 10°.

In an embodiment, at least in a range of the small incident angle, the comparison is performed under the situation that the first incident angle a and the third incident angle c are any angles within the range of 0° to 10°, the reflectivity of the first insulating reflective layer 16 is lower than the reflectivity of the second insulating reflective layer 18. In an embodiment, the comparison is performed under the situation that the first incident angle a is equal to the third incident angle c, the reflectivity of the first insulating reflective layer 16 is lower than the reflectivity of the second insulating reflective layer 18.

In an embodiment, for the light incident on the surface of the first insulating reflective layer 16 at a large angle, the reflectivity of the first insulating reflective layer 16 maintains the characteristics of the traditional insulating reflective layer, and the reflectivity is relatively high, for example, the reflectivity is higher than 90%. The light at the large incident angle is reflected by the first insulating reflective layer 16, and is reflected to the first surface 144 or reflected to the side surface of the substrate 12, thereby emitting light, which can improve the light intensity ratio of large-angle light emission, and ensures the overall brightness of the whole light-emitting diode 1.

For the first insulating reflective layer 16, the light incident at a large angle is defined as light with a second incident angle b, and the first incident angle a is smaller than the second incident angle b. That is, the light with the first incident angle a is small-angle light, and the light with the second incident angle b is large-angle light.

In an embodiment, for the light with the second incident angle b, the reflectivity of the first insulating reflective layer 16 is at least 90%. In an embodiment, the second incident angle is in a range of 60° to 90°.

In an embodiment, the second insulating reflective layer 18 is located on a side of the second surface 145, and light incident on the surface of the second insulating reflective layer 18 at a large incident angle is defined as light with a fourth incident angle d. The fourth incident angle d is greater than the third incident angle c, that is, the light with the third incident angle c is small-angle light, and the light with the fourth incident angle d is large-angle light. Reflectivity of the second insulating reflective layer 18 to the light with the third incident angle c is relatively high. In an embodiment, the reflectivity of the second insulating reflective layer 18 to the light with the third incident angle c is at least 90%.

In an embodiment, the reflectivity of the first insulating reflective layer 16 to the light with the second incident angle b is higher than the reflectivity of the second insulating reflective layer 18 to the light with the fourth incident angle d. In an embodiment, the reflectivity of the first insulating reflective layer 16 to the light with the first incident angle a is lower than the reflectivity of the first insulating reflective layer 16 to the light with the second incident angle b.

In an embodiment, the second insulating reflective layer 18 has relatively low reflectivity for large-angle light, when transmissivity of the second insulating reflective layer 18 to the light with the fourth incident angle d is improved, for example, the reflectivity of the second insulating reflective layer 18 to the light with the fourth incident angle d is higher than 90%, a length of a light-emitting path of the large-angle light is reduced, and a ratio of direct light emission of the large-angle light is improved (i.e., the large-angle light is directly emitted from the surface of the second insulating reflective layer 18), thereby improving the overall brightness of the light-emitting diode 1. In an embodiment, the fourth incident angle d is greater than the second incident angle b, and the fourth incident angle is in a range of 60° to 80°. The reflectivity of the second insulating reflective layer 18 on the light with the fourth incident angle d can be 95%, 96%, 97%, 98% or 99%.

Overall, the amount of light emitted by the light-emitting diode 1 in a direction close to the vertical is decreased, and the ratio of the amount of light emitted at large angles by the light-emitting diode 1 in the direction close to the horizontal is increased. Finally, an angle range of the light emitted from the side surface of the light-emitting diode 1 is improved, which increasing an extreme light emission angle of the light-emitting diode 1. In addition, the second insulating reflective layer 18 can transmit the large-angle light, thereby avoiding the light being reflected back and forth by the DBR layers on both sides of the substrate, and reducing internal light loss.

It should be noted that for the second insulating reflective layer 18, for light with an incident angle of 0° to 90° on the vertical direction and the horizontal direction, and for light with an incident angle between the third incident angle c and the fourth incident angle d, for example, light with an incident angle of 10° to 60°, the second insulating reflective layer 18 can have reflectivity higher than 90%, can also have reflectivity lower than 90%. The second insulating reflective layer 18 can be optimized and adjusted according to actual brightness requirements or angle range requirements of emitted light of the light-emitting diode 1. For example, the range of the third incident angle c can exceed 20°, for example, 0° to 30° or 0° to 40° is selected. In an embodiment, the range of the third incident angle c does not exceed 50°.

Similarly, for the first insulating reflective layer 16, for the light with the incident angle of 0° to 90° on the vertical direction and the horizontal direction, and for light with an incident angle between the first incident angle a and the second incident angle b, for example, light with an incident angle of 10° to 60°, the first insulating reflective layer 16 can have reflectivity higher than 90%, can also have reflectivity lower than 90%. But not limited thereto, the range of the first incident angle a can exceed 10°, for example, 0° to 20°, 0° to 30° or 0° to 40° is selected. In an embodiment, the range of the first incident angle a does not exceed 50°. The first insulating reflective layer 16 can be optimized and adjusted according to the actual brightness requirements or angle range requirements of emitted light of the light-emitting diode 1.

In an embodiment, as shown in FIG. 2, based on the brightness requirements of light, the reflectivity of the first insulating reflective layer 16 should not be too low no matter for the small-angle light or the large-angle light, which may cause serious light loss. In an embodiment, the reflectivity of the first insulating reflective layer 16 is higher than the transmissivity of the first insulating reflective layer 16, or the reflectivity of the first insulating reflective layer 16 on light with any angle exceeds 50%.

In an embodiment, as shown in FIG. 2, based on the brightness requirements of light, the reflectivity of the first insulating reflective layer 16 to the light with the first incident angle a is lower than the reflectivity of the first insulating reflective layer 16 to the light with the second incident angle b.

Through the above methods, the first insulating reflective layer 16 partially transmits the light with the smaller incident angle, and reflects the light with the large incident angle, to increase the ratio of large-angle light emission. The second insulating reflective layer 18 reflects the light with the small incident angle, and reflects more light to the first insulating reflective layer 16, thereby reducing the ratio of the light with the small incident angle directly emitted from above the substrate 12. The second insulating reflective layer 18 can transmit the light with the large incident angle, to further increase lateral light emission angle and light emission amount. Finally, the lateral light emission amount of the light-emitting diode 1 is increased, and the lateral light emission angle of the light-emitting diode 1 is increased.

In an embodiment, for the light with the third incident angle c, the reflectivity of the second insulating reflective layer 18 is higher than the transmissivity of the second insulating reflective layer 18. For the fourth incident angle d, the reflectivity of the second insulating reflective layer 18 may be lower than the transmissivity of the second insulating reflective layer 18.

In an embodiment, at least in a range of the large angle, the comparison is performed under the situation that the second incident angle b and the fourth incident angle d are any angles within the range of 60° to 80°, the reflectivity of the first insulating reflective layer 16 is lower than the reflectivity of the second insulating reflective layer 18. In an embodiment, the comparison is performed under the situation that the second incident angle b and the fourth incident angle d are in the range of 60° to 80°, the reflectivity of the first insulating reflective layer 16 is higher than the reflectivity of the second insulating reflective layer 18.

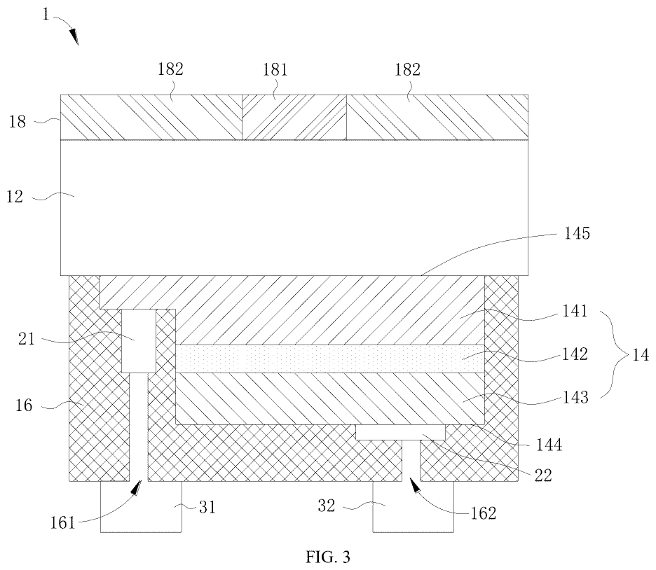

In an embodiment, as shown in FIG. 3, the second insulating reflective layer 18 has a relatively middle area 181 and relatively surrounding areas 182. For the light with the second incident angle b, transmissivity of the middle area 181 of the second insulating reflective layer 18 is lower than transmissivity of the surrounding areas 182 of the second insulating reflective layer 18, so that more light is emitted out from the side surface of the light-emitting diode 1, thereby improving the lateral light emission angle and the lateral light emission amount of the light-emitting diode 1. Specifically, the transmissivity of the middle area 181 lower than the transmissivity of the surrounding areas 182 can be achieved by changing thicknesses of the middle area 181 and the surrounding areas 182 of the second insulating reflective layer 18. Moreover, the transmissivity of the middle area 181 lower than the transmissivity of the surrounding areas 182 can be achieved by patterning the second insulating reflective layer 18.

In an embodiment, as shown in FIG. 1 and FIG. 3, the light-emitting diode 1 further includes a first electrode 21, a second electrode 22, a first solder pad 31 and a second solder pad 32. The first insulating reflective layer 16 defines a first opening 161 and a second opening 162. The first electrode 21 and the second electrode 22 are disposed on the first surface 144 of the epitaxial layer 14. The first electrode 21 is electrically connected to the first semiconductor layer 141, and the first solder pad 31 is electrically connected to the first electrode 21 through the first opening 161. The second electrode 22 is electrically connected to the second semiconductor layer 143, and the second solder pad 32 is electrically connected to the second electrode 22 through the second opening 162.

The first electrode 21 and the second electrode 22 can include reflective metals. For example, the first electrode 21 can include materials such as silver (Ag), nickel (Ni), aluminum (Al), chromium (Cr), rhodium (Rh), palladium (Pd), iridium (Ir), ruthenium (Ru), magnesium (Mg), zinc (Zn), platinum (Pt) and gold (Au), and can include a single-layer structure, or include a structure with two or more layers. The second electrode 22 can include at least one of Al, Au, Cr, Ni, titanium (Ti) and tin (Sn).

The first solder pad 31 and the second solder pad 32 can include Au, Ag, Ti, tungsten (W), copper (Cu), Sn, Ni, Pt, Cr, NiSn, TiW, AuSn or their eutectic metals. The first solder pad 31 and the second solder pad 32 can be formed in a same process using same materials, thus they can have a same layer structure.

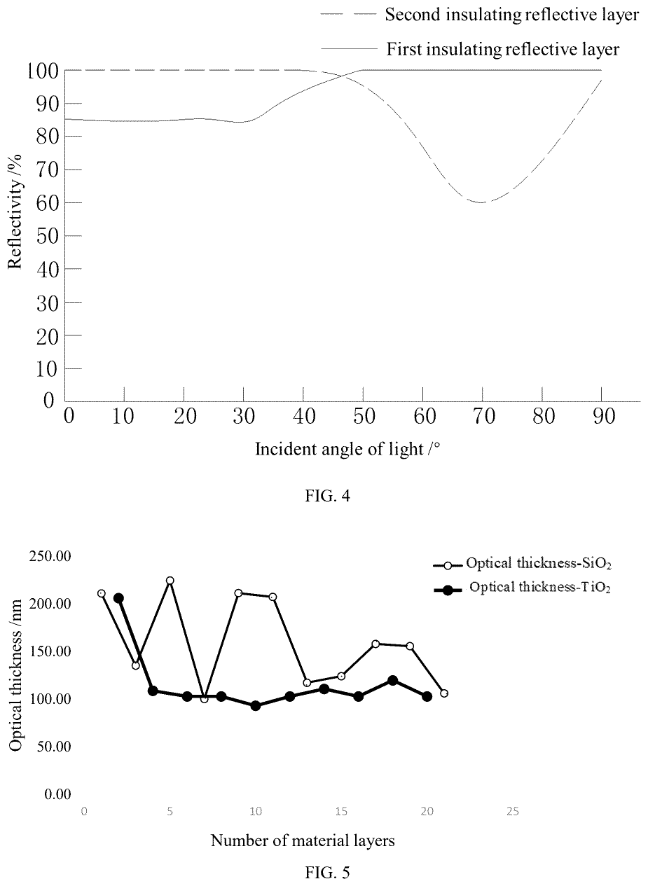

In an embodiment, as the reflection effect shown in FIG. 4, the reflectivity of the first insulating reflective layer 16 to the light with the small incident angle, that is, the light with the first incident angle a is lower than 90%, and the first incident angle a is in a range of 0° to 10°. In an embodiment, the reflectivity of the first insulating reflective layer 16 to light with an incident angle smaller than or equal to 30° is in a range of 80% to 90%. The reflectivity of the first insulating reflective layer 16 to the light with the large incident angle, that is, the light with the second incident angle b is higher than 90%, and the second incident angle a is in a range of 60° to 90°. In an embodiment, the reflectivity of the first insulating reflective layer 16 to light with an incident angle greater than or equal to 60° is higher than 95%. The reflectivity of the second insulating reflective layer 18 to the light with the third incident angle c is higher than 90%. In an embodiment, the reflectivity of the second insulating reflective layer 18 to the light with an incident angle greater than or equal to 0° and smaller than or equal to 20° is higher than 95%. The reflectivity of the second insulating reflective layer 18 to the light with the fourth incident angle d is lower than 90%. In an embodiment, the reflectivity of the second insulating reflective layer 18 to the light with an incident angle greater than or equal to 60° and smaller than or equal to 80° is lower than 90%. Overall, the first insulating reflective layer 16 has low reflectivity to the light with the small incident angle, and has high reflectivity to the light with the large incident angle, the second insulating reflective layer 18 has high reflectivity to the light with the small incident angle, and has low reflectivity to the light with the large incident angle, thereby improving the lateral light emission angle of the light-emitting diode 1, and increasing the extreme light emission angle of the light-emitting diode 1.

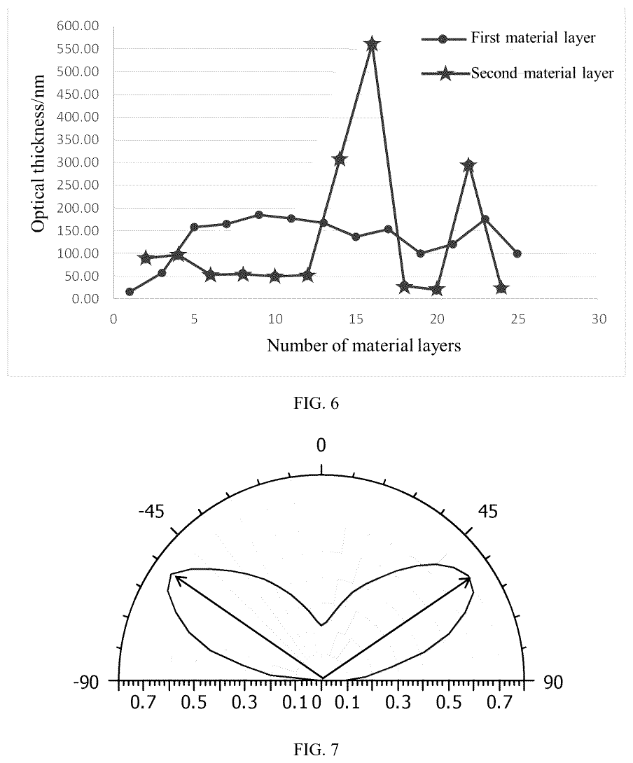

In an embodiment, as shown in FIG. 5 and FIG. 6, in order to ensure that the first insulating reflective layer 16 and the second insulating reflective layer 18 have different transmissivity and reflectivity according to different incident angles, stacked numbers of the first insulating reflective layer 16 and the second insulating reflective layer 18 can be designed to be smaller than a stacked number of a general DBR layer, and the thicknesses of the first insulating reflective layer 16 and the second insulating reflective layer 18 are thinner than that of the general DBR layer. For example, the DBR layer can be formed by repeatedly stacking each dielectric film (silica or titanium oxide) 5 to 15 times.

In an embodiment, as shown in FIG. 5, due to improved design of the first insulating reflective layer 16 (generally, the thickness is in a range of 2 μm to 3 μm, and a number of pairs of the dielectric films is in a range of 15 pairs to 20 pairs), the reflectivity of the first insulating reflective layer 16 to the light with the small incident angle is reduced. Therefore, the thickness of the first insulating reflective layer 16 can be reduced relative to the thickness of the traditional DBR layer. The thickness of the first insulating reflective layer 16 can be between 4 μm and below, that is, the thickness of the first insulating reflective layer 16 can be lower than or equal to 4 μm, and a number of pairs of the dielectric films can be reduced to 12 pairs and below 12 pairs.

In an embodiment, as shown in FIG. 6, the thickness of the second insulating reflective layer 18 can be between 3 μm and below, that is, the thickness of the second insulating reflective layer 18 can be lower than or equal to 3 μm, and the number of pairs of the dielectric films can be in a range of 5 pairs to 15 pairs. The first insulating reflective layer 16 is thicker than the second insulating reflective layer 18, and the number of pairs of the dielectric films of the first insulating reflective layer 16 is more than that of the second insulating reflective layer 18. The first insulating reflective layer 16 and the second insulating reflective layer 18 can have different reflectivity and transmissivity to the light with different incident angles through the DBR layer (i.e., first insulating reflective layer 16 and the second insulating reflective layer 18) designed by optical thickness.

In an embodiment, as shown in FIG. 7, by setting the selection reflection of the first insulating reflective layer 16 and the second insulating reflective layer 18 on the light with different incident angles, an included angle of lateral extreme light emission is about 120°, a ratio of light intensity of the lateral extreme light to light intensity of axial light is about 3.3, so that a large amount of light is emitted out form the side surface of the light-emitting diode 1, increasing the lateral light emission angle and the extreme light emission angle, thereby making light distribution of the light emitted by the light-emitting diode 1 in a shape of a bat wing.

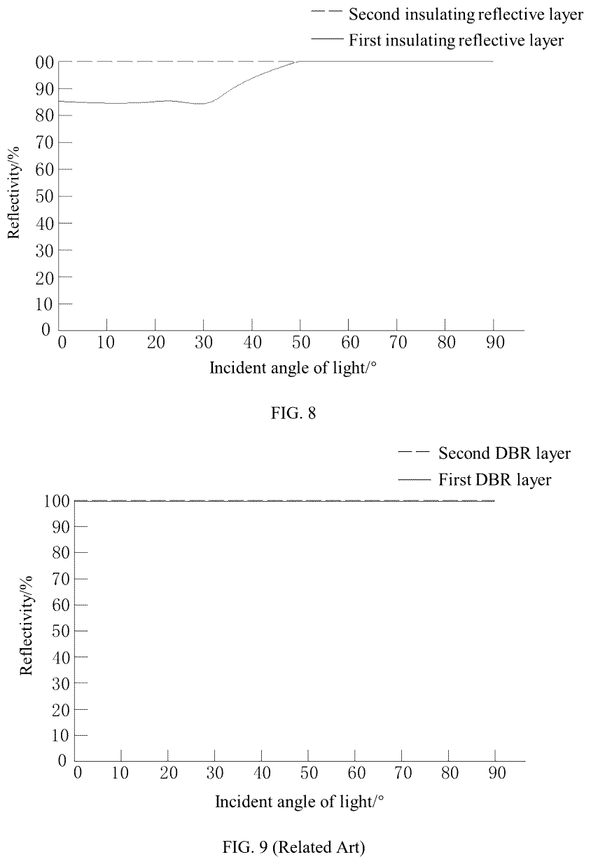

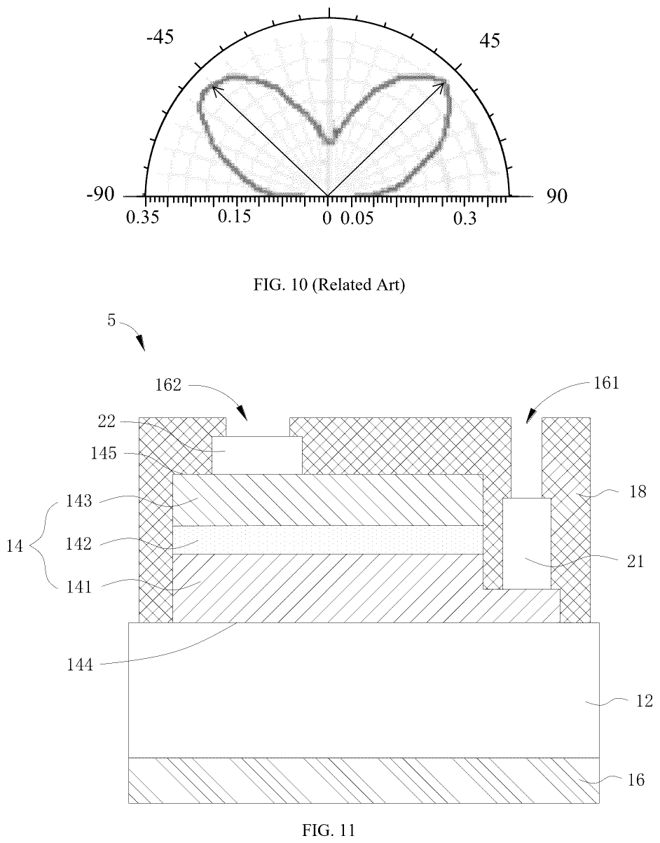

In an embodiment, as the reflection effect shown in FIG. 8, by only using the way that the first insulating reflective layer 16 has different reflectivity to the light with different incident angles, the lateral light emission angle of the light-emitting diode 1 is improved, and the extreme light emission angle of the light-emitting diode 1 is increased. Specifically, the reflectivity of the first insulating reflective layer 16 to the light with the first incident angle a is lower than 90%. In an embodiment, the reflectivity of the first insulating reflective layer 16 to the light with an incident angle smaller than or equal to 10° is in a range of 80% to 90%. The reflectivity of the first insulating reflective layer 16 to the light with the second incident angle b is higher than 90%. In an embodiment, the reflectivity of the first insulating reflective layer 16 to the light with an incident angle greater than or equal to 60° is higher than 95%. The second insulating reflective layer 18 has high reflectivity to the light with any incident angle, and its reflectivity can be higher than 95%. In an embodiment, the reflectivity of the second insulating reflective layer 18 is close to 100%. Since the first insulating reflective layer 16 has low reflectivity to the light with the small incident angle, and has high reflectivity to the light with the large incident angle, and the second insulating reflective layer 18 has high reflectivity, the lateral light emission angle of the light-emitting diode 1 can be improved, and the extreme light emission angle of the light-emitting diode 1 can be increased. It should be noted that since the reflectivity of the first insulating reflective layer 16 and the second insulating reflective layer 18 to the light with relatively large incident angle shown in FIG. 8 is close to 100%, the latter half of the line segment in the diagram overlaps. In addition, the included angle of the lateral extreme light emission in the embodiment is about 115°, and the ratio of the light intensity of the lateral extreme light to the light intensity of the axial light is about 2.5.

It should be added that the first insulating reflective layer 16 and the second insulating reflective layer 18 are not limited to the DBR layer, and may be other reflective structures that can have different reflectivity and transmissivity according to different incident angles.

An embodiment of the disclosure can further provide a light-emitting device, the light-emitting device includes the light-emitting diode 1 provided by the aforementioned embodiments, and its specific structure and technical effects are not repeated.

In an embodiment, the light-emitting diode 1 can be applied in a direct-lit backlight display field, the flip-chip light-emitting diodes 1 with small sizes are integrated in quantities of hundreds, thousands, or tens of thousands and mounted on an application substrate or a packaging substrate in a flip chip manner (for example, being connected to the substrate through solder paste or tin element included in the pad electrode of the light-emitting diode 1), to form a light-emitting source part of the backlight display device. The small size may be a Mini-LED chip with an area smaller than 90000 square microns (μm²).

In summary, the disclosure provides a light-emitting diode 1 and a light-emitting device, through the settings of selective reflection of the first insulating reflective layer 16 and the second insulating reflective layer 18 for different incident light, axial light emission of the light-emitting diode 1 can be reduced, lateral light emission of the light-emitting diode 1 can be increased, which greatly improves a lateral light emission angle of the light-emitting diode 1, and increases an extreme light emission angle of the light-emitting diode 1, thereby meeting requirement of light-emitting uniformity.

In addition, as an alternative embodiment, as shown in FIG. 11, the light-emitting diode can also be a front-chip light-emitting diode 5 with a conventional size, which is a Mini-LED with an area greater than 90000 μm². Compared to the flip-chip light-emitting diode 1 shown in FIG. 1, a light-transmitting substrate 12 of the front-chip light-emitting diode 5 is located between the first insulating reflective layer 16 and the epitaxial layer 14. Moreover, as it is a front-chip light-emitting diode 5, there is no need to set up the first solder pad 31 and the second solder pad 32. The first electrode 21 and the second electrode 22 are respectively exposed from the first opening 161 and the second opening 162, which is conductive for connecting wires in subsequent manufacturing processes. In an embodiment, the front-chip light-emitting diode 5 can be applied in the direct-lit backlight display field or the edge-lit backlight display field, and the front-chip light-emitting diodes with the conventional size are integrated (by wire bonding, such as gold wire) in quantities of tens or hundreds and mounted on the application substrate or the packaging substrate, to form the light-emitting source part of the backlight display device.

It should be noted that curves about reflectivity of the disclosure are obtained by the following methods. A glass substrate (borosilicate crown glass (BK7 glass) instead of the epitaxial layer) is used as a medium, and a thickness of the glass substrate is 1 millimeter (mm). A titanium oxide film and a silica film are plated on a side of the glass substrate as an insulating reflective film formed by alternatively stacking the high refractive index films and low refractive index films, and the insulating reflective film is used as the test object. A reflectivity tester provides a light source with a light-emitting wavelength of 444 nm (which is the central radiation wavelength of the light emitted by the light-emitting diode), the light emitted by the light source is incident on the glass substrate and reaches the interface between the glass substrate and the insulating reflective film, then is reflected by the insulating reflective film, and is emitted from the glass substrate for collection. The reflectivity tester tests the light reflectivity of the insulating reflective film. The reflectivity of the insulating reflective layer can be obtained by an optical thin film analysis and design software, such as a soft ware named as Essential Macleod®.

In addition, those skilled in the art should understand that although there are many problems in the related art, each embodiment or technical solution of the disclosure can only be improved in one or several aspects, and it is not necessary to solve all technical problems listed in the related art or background art at the same time. It should be understood by those skilled in the art that anything that is not mentioned in claims should not be taken as a limitation on the claims.

Finally, it should be noted that the above embodiments are merely used to illustrate the technical solutions of the disclosure, rather than limiting them. Although the disclosure has been described in detail with reference to the foregoing embodiments, those skilled in the art should understand that it is still possible to modify the technical solutions described in the foregoing embodiments, or perform equivalent replacements for some or all of the technical features. These modifications or replacements do not make the essence of the corresponding technical solutions deviate from the scope of the technical solutions of the various embodiments of the disclosure.

What is claimed is:

1. A light-emitting diode, comprising:
an epitaxial layer, comprising a first semiconductor layer, a light-emitting layer configured to emit light, and a second semiconductor layer sequentially stacked in that order, and having a first surface and a second surface opposite to each other;
a first insulating reflective layer, disposed on a side of the first surface of the epitaxial layer; and
a second insulating reflective layer, disposed on a side of the second surface of the epitaxial layer; and
wherein reflectivity of the first insulating reflective layer to light with a first incident angle is lower than reflectivity of the second insulating reflective layer to light with a third incident angle, the first incident angle is in a range of 0° to 10°, and the third incident angle is in a range of 0° to 10°.

2. The light-emitting diode as claimed in claim 1, wherein the reflectivity of the first insulating reflective layer to the light with the first incident angle is lower than 90%, reflectivity of the first insulating reflective layer to light with a second incident angle is at least 90%, the second incident angle is greater than the first incident angle, and the second incident angle is in a range of 60° to 90°.

3. The light-emitting diode as claimed in claim 2, wherein the reflectivity of the first insulating reflective layer to the light with the second incident angle is higher than reflectivity of the second insulating reflective layer to light with a fourth incident angle, and the second incident angle and the fourth incident angle are in a range of 60° to 80°.

4. The light-emitting diode as claimed in claim 2, wherein a central radiation wavelength of the light emitted by the light-emitting layer is in a range of 430 nm to 460 nm.

5. The light-emitting diode as claimed in claim 2, wherein the reflectivity of the second insulating reflective layer to the light with the third incident angle is at least 90%.

6. The light-emitting diode as claimed in claim 2, wherein reflectivity of the second insulating reflective layer to light with a fourth incident angle is lower than 90%, and the fourth incident angle is in a range of 60° to 80°.

7. The light-emitting diode as claimed in claim 1, wherein each of the first insulating reflective layer and the second insulating reflective layer comprises a multilayer structure formed by repeatedly stacking first refractive index material layers and second refractive index material layers.

8. The light-emitting diode as claimed in claim 1, wherein the light-emitting diode is a flip-chip light-emitting diode, and a light-transmitting substrate is disposed between the second insulating reflective layer and the epitaxial layer.

9. The light-emitting diode as claimed in claim 1, wherein a thickness of the first insulating reflective layer is smaller than or equal to 4 μm, and a thickness of the second insulating reflective layer is smaller than or equal to 3 μm.

10. The light-emitting diode as claimed in claim 1, wherein the light-emitting diode is a front-chip light-emitting diode, and a light-transmitting substrate is disposed between the first insulating reflective layer and the epitaxial layer.

11. A light-emitting diode, comprising:
an epitaxial layer, comprising a first semiconductor layer, a light-emitting layer configured to emit light, and a second semiconductor layer sequentially stacked in that order, and having a first surface and a second surface opposite to each other; and
a first insulating reflective layer, disposed on a side of the first surface of the epitaxial layer; and
wherein reflectivity of the first insulating reflective layer to light with a first incident angle is lower than 90%, and the first incident angle is in a range of 0° to 10°.

12. The light-emitting diode as claimed in claim 11, wherein reflectivity of the first insulating reflective layer to light with a second incident angle is higher than the reflectivity of the first insulating reflective layer to the light with the first incident angle, the reflectivity of the first insulating reflective layer to the light with the second incident angle is at least 90%, the second incident angle is greater than the first incident angle, and the second incident angle is in a range of 60° to 90°.

13. The light-emitting diode as claimed in claim 11, wherein a central radiation wavelength of the light emitted by the light-emitting layer is in a range of 430 nm to 460 nm.

14. The light-emitting diode as claimed in claim 11, further comprising:
a second insulating reflective layer, disposed on a side of the second surface of the epitaxial layer; wherein reflectivity of the second insulating reflective layer to light with a third incident angle is at least 90%, and the third incident angle is in a range of 0° to 20°.

15. The light-emitting diode as claimed in claim 14, wherein reflectivity of the second insulating reflective layer to light with a fourth incident angle is lower than 90%, and the fourth incident angle are in a range of 60° to 80°.

16. A light-emitting diode, comprising:
an epitaxial layer, comprising a first semiconductor layer, a light-emitting layer configured to emit light, and a second semiconductor layer sequentially stacked in that order, and having a first surface and a second surface opposite to each other; and
a first insulating reflective layer, disposed on a side of the first surface of the epitaxial layer; and
wherein reflectivity of the first insulating reflective layer to light with a first incident angle is lower than reflectivity of the first insulating reflective layer to light with a second incident angle, and the first incident angle is smaller than the second incident angle.

17. The light-emitting diode as claimed in claim 16, wherein the first incident angle is in a range of 0° to 10°, and the second incident angle is in a range of 60° to 90°.

18. The light-emitting diode as claimed in claim 16, wherein the reflectivity of the first insulating reflective layer to the light with the first incident angle is lower than 90%, and the reflectivity of the first insulating reflective layer to the light with the second incident angle is at least 90%.

19. The light-emitting diode as claimed in claim 16, further comprising:
a second insulating reflective layer, disposed on a side of the second surface of the epitaxial layer; wherein reflectivity of the second insulating reflective layer to light with a third incident angle is higher than reflectivity of the second insulating reflective layer to light with a fourth incident angle, the third incident angle is smaller than the fourth incident angle, the third incident angle is in a range of 0° to 20°, and the fourth incident angle are in a range of 60° to 80°; and the reflectivity of the second insulating reflective layer to the light with the third incident angle is at least 90%, and the reflectivity of the second insulating reflective layer to the light with the fourth incident angle is lower than 90%.

20. A light-emitting device, comprising the light-emitting diode as claimed in claim 1.
